(19) United States
(12) Patent Application Publication
(10) Pub. No.: US 2026/0358444 A1
(43) Pub. Date: Nov. 12, 2026

(54) MAGNETIC SENSOR, MAGNETORESISTIVE ELEMENT, AND METHOD FOR MANUFACTURING MAGNETIC SENSOR

(71) Applicant: TDK Corporation, Tokyo (JP)

(72) Inventor: Hiroki OMURA, Tokyo (JP)

(21) Appl. No.: 19/457,450

(22) Filed: Jan. 23, 2026

(30) Foreign Application Priority Data
Feb. 18, 2025 (JP) 2025-024047

(51) Int. Cl. G01R 33/09

(52) U.S. Cl. CPC G01R 33/098; G01R 33/093

(57) ABSTRACT

Magnetoresistive elements (3) have a magnetically free layer (45), a magnetically pinned layer (43), and a nonmagnetic layer (44) arranged in a first direction (Z). Nonmagnetic layer (44) is between magnetically free layer 45 and magnetically pinned layer (43). The magnetization directions of the magnetically pinned layers (43) of the first and second element units (11, 12) are oriented in opposite directions in the first direction (Z). The magnetically free layer (45) is magnetized in a vortex shape in the absence of an external magnetic field, the magnetization direction of the magnetically free layer (45) is variable in accordance with an external magnetic field, and the magnetization direction of the center of the vortex shape of the magnetically free layer (45) is oriented in the direction opposite to the magnetization direction of the magnetically pinned layer (43) in the absence of an external magnetic field.

### FIELD

This application claims the benefit of Japanese Priority Patent Application No. 2025-024047 filed on Feb. 18, 2025, the entire contents of which are incorporated herein by reference.

The present disclosure relates to a magnetic sensor, a magnetoresistive element, and method for manufacturing a magnetic sensor.

### BACKGROUND

JP2023-553931A describes a magnetoresistive element having a magnetically free layer magnetized in a vortex shape in the absence of an external magnetic field (zero magnetic field state) and a magnetically pinned layer whose magnetization direction is fixed in the film thickness direction. In a zero magnetic field state, the center of the vortex shape of the magnetically free layer is magnetized in the film thickness direction.

### SUMMARY

One object of the present disclosure is to provide a magnetic sensor that comprises magnetoresistive elements each having a magnetically free layer magnetized in a vortex shape in a zero magnetic field state and a magnetically pinned layer whose magnetization direction is fixed in the film thickness direction, and in which the magnetization direction in the center of a vortex shape of each magnetically free layer is controlled in the absence of an external magnetic field.

A magnetic sensor of the present disclosure comprises element units, each of which comprises at least one magnetoresistive element. The element units comprise a first element unit and a second element unit, the first element unit and the second element unit being connected in series to form a first group. One end of the first group is connected to a power supply and other end is grounded. The first element unit is located on the side of the power supply, and the second element unit is located on the grounded side. Each magnetoresistive element has a magnetically free layer, a magnetically pinned layer, and a nonmagnetic layer arranged in a first direction, the nonmagnetic layer being located between the magnetically free layer and the magnetically pinned layer. The magnetization direction of the magnetically pinned layer of at least one magnetoresistive element included in the first element unit and the magnetization direction of the magnetically pinned layer of at least one magnetoresistive element included in the second element unit are oriented in the first direction but in opposite directions. In each magnetoresistive element, the magnetically free layer is magnetized in a vortex shape in a plane perpendicular to the first direction in the absence of an external magnetic field, the magnetization direction of the magnetically free layer is variable in accordance with an external magnetic field, and the magnetization direction of the center of the vortex shape of the magnetically free layer is oriented in the first direction and in the direction opposite to the magnetization direction of the magnetically pinned layer in the absence of an external magnetic field.

### BRIEF DESCRIPTION OF DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a drawing showing the general structure of a magnetic sensor according to one example embodiment of the present disclosure.

FIG. 2 is a schematic side view of a magnetoresistive element.

FIG. 3 is a schematic oblique view of a magnetically free layer, a nonmagnetic layer, and a first magnetically pinned layer.

FIG. 4 is a schematic view showing the relationship between an external magnetic field and the magnetic moment of the magnetically free layer.

FIG. 5 is a cross-sectional view of the nonmagnetic layer in a cross section that is parallel to the Z-direction.

FIG. 6A-6B are schematic views showing the principle of generating cancelling magnetic fields.

FIG. 7A-7B are drawings showing a first method for determining the shape characteristic values of a concavo-convex shape of the centerline of the nonmagnetic layer.

FIG. 8A-8B are drawings showing a second method for determining the shape characteristic values of a concavo-convex shape of the centerline of the nonmagnetic layer.

FIG. 9A-9B are drawings showing a third method for determining the shape characteristic values of a concavo-convex shape of the centerline of the nonmagnetic layer.

FIG. 10A-10B are drawings showing a fourth method for determining the shape characteristic values of a concavo-convex shape of the centerline of the nonmagnetic layer.

FIG. 11A-11C are drawings showing a method for defining the magnetization direction of the core of a magnetically free layer.

FIG. 12A-12C are drawings showing a method for defining the magnetization direction of the core of a magnetically free layer of a magnetic sensor in a bridge structure according to the example embodiment.

FIG. 13A-13C are drawings showing a method for defining the magnetization direction of the core of a magnetically free layer of a magnetic sensor in a bridge structure according to a comparative example.

FIG. 14 is a drawing showing the general structure of a magnetic sensor according to a variation of the present disclosure.

### DETAILED DESCRIPTION

In a zero magnetic field state, whether the magnetization direction of the center of a vortex shape of a magnetically free layer is oriented in the same direction as the magnetization direction of a magnetically pinned layer or is oriented in the direction opposite to the magnetization direction of the magnetically pinned layer is randomly determined. This random determination results in variation in the characteristics of each product, in particular, in magnetic sensors having a plurality of magnetoresistive elements.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

Example embodiments of the present disclosure will be described with reference to the drawings. In the following description and drawings, the film thickness direction of magnetically free layer 45, or the direction in which first magnetically pinned layer 43, nonmagnetic layer 44, and magnetically free layer 45 are arranged (stacked) is referred to as the first direction (Z-direction). The direction from substrate 2 to magnetically free layer 45 is referred to as the +Z-direction, and the direction from magnetically free layer 45 to substrate 2 is referred to as the −Z-direction. When the +Z-direction and the −Z-direction need not be distinguished, these directions may be referred to as the Z-direction. The X-direction is a direction orthogonal to the +Z-direction. The X-direction is shown in the drawings for convenience but is not limited to the direction shown. The X-direction should be orthogonal to the +Z-direction.

### Overall Structure of Magnetic Sensor

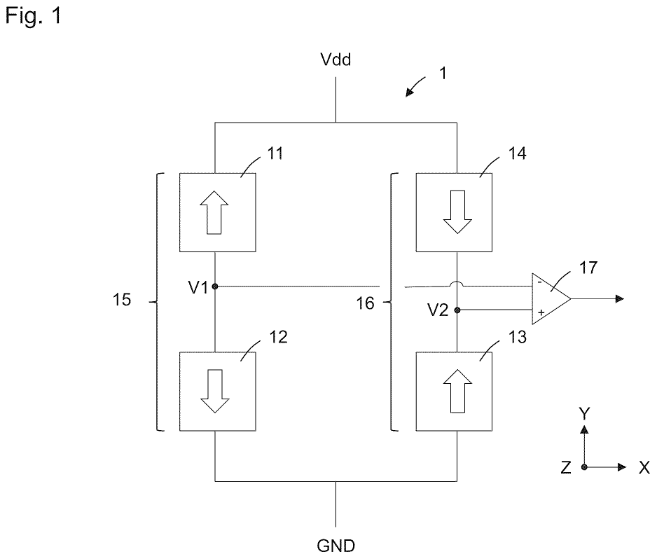

FIG. 1 shows a schematic diagram of magnetic sensor 1 of the first example embodiment. The white arrows indicate the magnetization directions of first magnetically pinned layer 43 (described below). Magnetic sensor 1 of this example embodiment may have element units, and the element units may comprise first through fourth element units 11-14. First element unit 11 and second element unit 12 may be connected in series to form first group 15, and third element unit 13 and fourth element unit 14 may be connected in series to form second group 16. One end of first group 15 and one end of second group 16 may be connected to power supply Vdd and the other ends may be grounded. First element unit 11 and fourth element unit 14 may be located on the power supply Vdd side, and second element unit 12 and third element unit 13 may be located on the grounded side (GND). Magnetic sensor 1 may have differential circuit 17 for determining the difference between midpoint voltage V1 that is between first element unit 11 and second element unit 12 and midpoint voltage V2 that is between third element unit 13 and fourth element unit 14.

Each of first through fourth element units 11-14 may comprise at least one magnetoresistive element 3. Although not shown in the drawings, each of first through fourth element units 11-14 may comprise several to several hundred magnetoresistive elements 3 connected in series. The magnetization directions of first magnetically pinned layers 43 of all magnetoresistive elements 3 of first element unit 11 and third element unit 13 may be the same direction. The magnetization directions of first magnetically pinned layers 43 of all magnetoresistive elements 3 of second element unit 12 and fourth element unit 14 may be opposite to the magnetization direction of first magnetically pinned layers 43 of all magnetoresistive elements 3 of first element unit 11 and third element unit 13. As a result, the ratio of the electrical resistance of first element unit 11 to the electrical resistance of second element unit 12, and the ratio of the electrical resistance of third element unit 13 to the electrical resistance of fourth element unit 14 may change when an external magnetic field is applied.

The voltage drop at each element unit 11-14 may be for the most part proportional to the electrical resistance of element units 11-14. Therefore, when the electrical resistance of each of first through fourth element units 11-14 is R1-R4, respectively, midpoint voltage V1 satisfies V1=R2/(R1+R2)×Vdd and midpoint voltage V2 satisfies V2=R3/(R3+R4)×Vdd. By obtaining differential output V1-V2 of midpoint voltages V1 and V2 by differential circuit 17, the sensitivity is doubled compared to detecting the midpoint voltages V1 and V2. Even if midpoint voltages V1 and V2 are offset, the effect of the offset can be eliminated by detecting the difference.

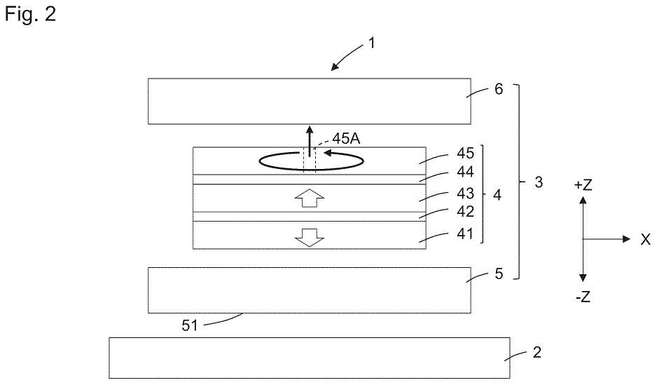

FIG. 2 is a schematic side view of magnetoresistive element 3. The white arrows indicate the magnetization directions of first magnetically pinned layer 43 and second magnetically pinned layer 41. The bold lines with arrows indicate the magnetization directions of magnetically free layer 45 in the absence of an external magnetic field (hereinafter referred to as the zero magnetic field state). The external magnetic field is the magnetic field to be detected and does not include the magnetic field generated inside magnetoresistive element 3. In this example embodiment, magnetic sensor 1 may include substrate 2 and magnetoresistive element 3. Magnetoresistive element 3 may include magnetic field detector 4 and first and second electrode layers 5 and 6 that supply a sense current. First and second electrode layers 5 and 6 may sandwich magnetic field detector 4 in the Z-direction, and first electrode layer 5 may be located between substrate 2 and magnetic field detector 4. Although not shown in the drawing, other layers can be provided between first electrode layer 5 and substrate 2, and first electrode layer 5 may be separated from substrate 2. Substrate 2 may be formed of silicon or the like. First electrode layer 5 and second electrode layer 6 may be formed of laminated films or the like made of conductors such as Ta, Cu, and Ru.

### Structure of Magnetic Field Detector 4

Magnetic field detector 4 may comprise magnetically free layer 45, nonmagnetic layer 44, first magnetically pinned layer 43, intermediate layer 42, and second magnetically pinned layer 41. These layers 41-45 may be arranged in the order of second magnetically pinned layer 41, intermediate layer 42, first magnetically pinned layer 43, nonmagnetic layer 44, and magnetically free layer 45 in the +Z-direction from first electrode layer 5 to second electrode layer 6, and the adjacent layers may be in contact with each other. These layers 41-45 may also be stacked in the opposite direction. Specifically, these layers 41-45 may be arranged in the order of second magnetically pinned layer 41, intermediate layer 42, first magnetically pinned layer 43, nonmagnetic layer 44, and magnetically free layer 45 in the −Z-direction from second electrode layer 6 to first electrode layer 5. Magnetic field detector 4 may be electrically connected to first and second electrode layers 5 and 6. A conductive layer such as a base layer (not shown) may be provided between magnetic field detector 4 and first electrode layer 5, and a conductive layer such as a cap layer (not shown) may be provided between magnetic field detector 4 and second electrode layer 6.

Magnetically free layer 45 is a magnetic layer whose magnetization direction changes with respect to an external magnetic field. Magnetically free layer 45 can be formed of, for example, CoFe, CoFeB, and NiFe. In a zero magnetic field state, magnetically free layer 45 may be magnetized in a vortex shape in a plane perpendicular to the Z-direction. The magnetization state of magnetically free layer 45 in the zero magnetic field state may depend on the balance between the exchange energy and the static magnetization energy of magnetically free layer 45. In general, a vortex-shaped magnetization state is more likely to occur when the saturation magnetization is large. In the zero magnetic field state, the center of the vortex (hereinafter referred to as core 45A) is located at generally the center of magnetically free layer 45, and the magnetization direction forms concentric circles around core 45A. In general, in a magnetically free layer that does not form a vortex magnetization state in the zero magnetic field state, the tendency for magnetization to incline with respect to a magnetic field in the Z-direction changes and the sensitivity of the magnetic sensor output tends to fluctuate when a magnetic field in an in-plane direction (X-direction) is applied. In a magnetically free layer that forms a vortex magnetization state in the zero magnetic field state, the tendency for magnetization to incline with respect to a magnetic field in the Z-direction does not easily change when a magnetic field in an in-plane direction (X-direction) is applied, and fluctuation in sensitivity is thus suppressed.

Nonmagnetic layer 44 may be located between magnetically free layer 45 and first magnetically pinned layer 43. Nonmagnetic layer 44 may be formed of an insulating layer such as MgO or Al₂O₃. Magnetoresistive element 3 in this example embodiment may operate as a tunnel magnetoresistive element (TMR element). Nonmagnetic layer 44 may be formed of a nonmagnetic metal layer such as copper or silver, in which case magnetoresistive element 3 may operate as a giant magnetoresistive element (GMR element). A TMR element tends to provide higher output than a GMR element.

First magnetically pinned layer 43 is a magnetic layer whose magnetization direction is fixed in the Z-direction with respect to an external magnetic field. In this example embodiment, first magnetically pinned layer 43 may be magnetically coupled to second magnetically pinned layer 41 by synthetic antiferromagnetic coupling through intermediate layer 42. First magnetically pinned layer 43 and second magnetically pinned layer 41 can be formed of multilayers of Co film and Pt film, or of materials with strong perpendicular magnetic anisotropy, such as multilayers of Co film and Pd film or multilayers of Co film and Ni film. Intermediate layer 42 may be made of a nonmagnetic metal that causes RKKY (Ruderman-Kittel-Kasuya-Yosida) coupling, such as ruthenium. Because the magnetization directions of first magnetically pinned layer 43 and second magnetically pinned layer 41 may be oriented in opposite directions, the leakage magnetic field applied from first magnetically pinned layer 43 to magnetically free layer 45 can be suppressed. In FIG. 1, first magnetically pinned layer 43 may be magnetized in the +Z-direction and second magnetically pinned layer 41 may be magnetized in the −Z-direction. However, first magnetically pinned layer 43 may be magnetized in the−Z-direction and second magnetically pinned layer 41 may be magnetized in the +Z-direction. The technology of the present disclosure is not limited to the configuration described above, and in some cases, a magnetic layer that does not contain synthetic antiferromagnetic coupling may be used as the magnetically pinned layers.

The magnetization direction of magnetically free layer 45 is changed by the application of an external magnetic field. Namely, when an external magnetic field including a component in the Z-direction is applied to magnetically free layer 45, the magnetization direction of magnetically free layer 45 may tilt in the Z-direction. This tilting may change the angle between the magnetization direction of magnetically free layer 45 and the magnetization direction of first magnetically pinned layer 43, and the electrical resistance of magnetic field detector 4 may change due to the magnetoresistive effect. By detecting the change in electrical resistance of magnetic field detector 4, the intensity of the Z-direction component of the external magnetic field can be measured. In this way, magnetic sensor 1 of this example embodiment may detect the magnetic field in the Z-direction.

Although not shown in the drawings, magnetic field detector 4 may include an antiferromagnetic layer. The antiferromagnetic layer can be provided on the side of second magnetically pinned layer 41 that is opposite the side of intermediate layer 42 and may be in contact with second magnetically pinned layer 41. The antiferromagnetic layer can be formed of, for example, IrMn, PtMn, or FeRh. The antiferromagnetic layer may be exchange-coupled with second magnetically pinned layer 41. When the antiferromagnetic layer is provided, the magnetization direction of second magnetically pinned layer 41 can be fixed more strongly than when the antiferromagnetic layer is not provided. For example, even if the magnetization direction of second magnetically pinned layer 41 reverses due to the application of a strong magnetic field, the magnetization direction of second magnetically pinned layer 41 returns to its original direction by exchange coupling with the antiferromagnetic layer when a zero magnetic field condition occurs. The magnetization direction of second magnetically pinned layer 41 in the zero magnetic field state may therefore be easily stabilized when the antiferromagnetic layer is provided, and reversal of output is unlikely to occur.

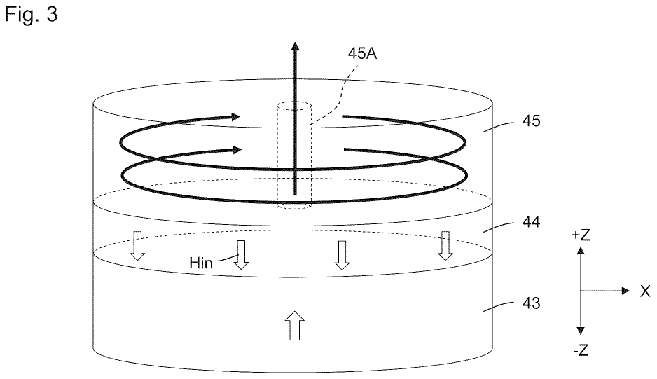

FIG. 3 shows a schematic oblique view of magnetically free layer 45, nonmagnetic layer 44, and first magnetically pinned layer 43. The cross-sectional shape of these layers 43-45 at each position in the Z-direction may be circular or approximately circular. Vortex-shaped magnetization states are more likely to occur in magnetically free layers that are rotationally symmetric in the Z-direction. The cross-sectional shape of magnetically free layer 45, nonmagnetic layer 44, and first magnetically pinned layer 43 as viewed in the Z-direction may therefore be not only circular but also elliptical or polygonal, such as a regular hexagon, square, or octagon.

### Magnetic Properties of Magnetically Free Layer 45

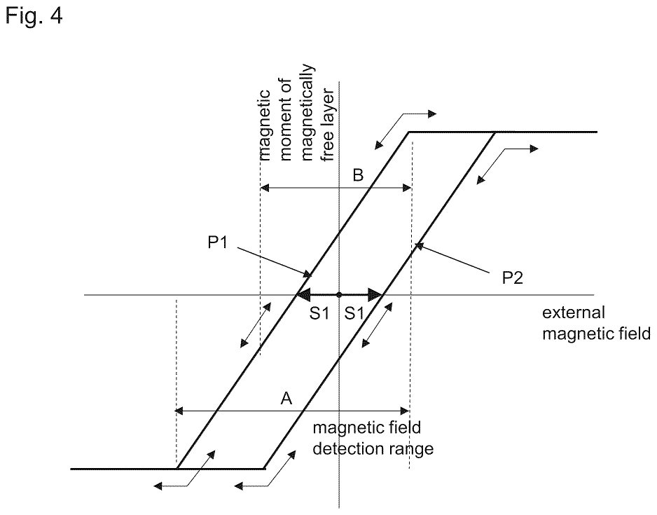

FIG. 4 schematically shows the relationship between an external magnetic field applied to magnetically free layer 45 and the magnetic moment of magnetically free layer 45 in a magnetoresistive element of a comparative example. The magnetic moment of magnetically free layer 45 may be offset in a zero magnetic field state. This offset occurs because the magnetization direction of core 45A of magnetically free layer 45 may be oriented in the Z-direction in a zero magnetic field state, and the average magnetization direction of magnetically free layer 45 may therefore be oriented in the Z-direction. In general, whether the magnetization direction of core 45A of magnetically free layer 45 is oriented in the +Z-direction or the −Z-direction is randomly determined. For example, even in a single wafer in which many magnetoresistive elements 1 are formed, the magnetization direction of core 45A may be different for each magnetoresistive element 1. No difference in performance may occur regardless of the direction of orientation of the magnetization of cores 45A. However, if the magnetization direction of core 45A cannot be controlled in each magnetoresistive element 3, characteristics may differ for each magnetic sensor 1, especially for magnetic sensors 1 having magnetoresistive elements 3 as in this example embodiment.

In this example embodiment, the manufacturing method described below can control the magnetization direction of core 45A of a magnetically free layer such that the magnetization direction of core 45A of the magnetically free layer and the magnetization direction of first magnetically pinned layer 43 are oriented in the Z-direction (first direction), and moreover, in opposite directions from each other in the zero magnetic field state. Because the magnetization direction of first magnetically pinned layer 43 can be controlled by the direction of a magnetizing process, the magnetization direction of corresponding core 45A of the magnetically free layer can be defined by the magnetization direction of first magnetically pinned layer 43. Eliminating the randomness of the magnetization direction of core 45A of the magnetically free layer enables setting of the magnetization direction of core 45A of the magnetically free layer to the intended orientation in all magnetoresistive elements 3 in a magnetic sensor.

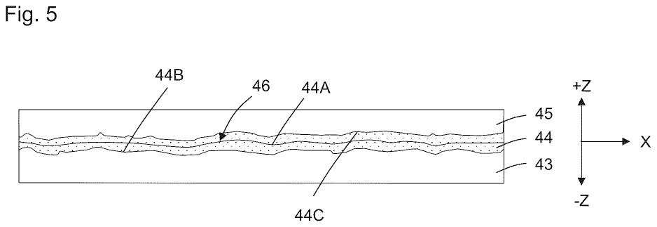

FIG. 5 shows a cross-sectional view of nonmagnetic layer 44 in a cross section parallel to the Z-direction. FIG. 5 also shows a part of magnetically free layer 45 and a part of first magnetically pinned layer 43. The left-right directions of the cross-sectional view are the X-direction. The shape characteristic values of concavo-convex shape 46 of nonmagnetic layer 44 (described below) may be almost the same in any cross section parallel to the Z-direction. Accordingly, the position in the cross section used to calculate the shape characteristic values is not particularly limited, but in order to ensure calculation accuracy, a position where a certain length in the cross-section (described below) can be obtained may be appropriately selected. A cross-sectional view can be obtained, for example, by transmission electron microscopy (TEM).

### Structure of Nonmagnetic Layer 44

In this example embodiment, nonmagnetic layer 44 may have an uneven shape. At least a part of, or the entire length of, centerline 44A of nonmagnetic layer 44, the corresponding boundary line 44B between nonmagnetic layer 44 and first magnetically pinned layer 43 and the corresponding boundary line 44C between nonmagnetic layer 44 and magnetically free layer 45 may have mutually similar uneven shapes. In this example embodiment, the uneven shape of center line 44A in particular is referred to as concavo-convex shape 46. At each point in the X-direction of nonmagnetic layer 44, centerline 44A is a line connecting points equidistant in the Z-direction from boundary line 44B with first magnetically pinned layer 43 and from boundary line 44C with magnetically free layer 45. By concavo-convex shape 46, a magnetic field oriented in the direction opposite to the magnetization direction of first magnetically pinned layer 43 (cancelling magnetic field Hin) may be applied to magnetically free layer 45. As described below, cancelling magnetic field Hin plays an important role in the initial setting of the magnetization direction of core 45A of magnetically free layer 45.

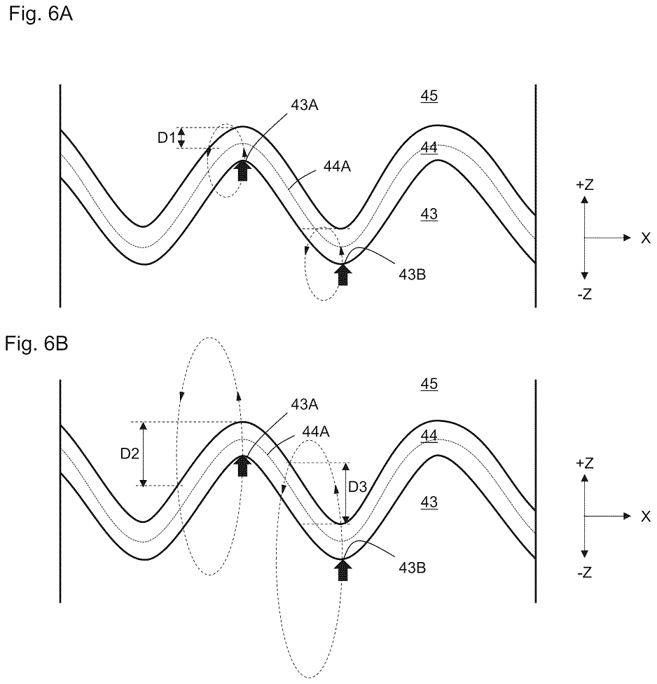

FIG. 6A-6B are partial enlarged views of first magnetically pinned layer 43, nonmagnetic layer 44, and magnetically free layer 45, and present simplified illustrations of the principle of the generation of cancelling magnetic field Hin. For the convenience of explanation, nonmagnetic layer 44 is assumed to have a sinusoidal concavo-convex shape. The dashed lines show magnetic flux. First magnetically pinned layer 43 may be magnetized in the +Z-direction, and, although not shown, core 45A of magnetically free layer 45 may also be magnetized in the +Z-direction.

FIG. 6A illustrates, of magnetic flux that enters and exits first magnetically pinned layer 43, magnetic flux that has a short path. The magnetic flux leaving top part 43A of first magnetically pinned layer 43 may pass through nonmagnetic layer 44, enter magnetically free layer 45, pass through nonmagnetic layer 44 again, and then return to first magnetically pinned layer 43. The magnetic flux leaving bottom part 43B of first magnetically pinned layer 43 may reverse course inside nonmagnetic layer 44 and thus may not enter magnetically free layer 45. Regarding the magnetic flux that leaves top part 43A of first magnetically pinned layer 43 and passes through the interior of magnetically free layer 45, the path length difference D1, which is the path length of the magnetic flux oriented in the −Z-direction minus the path length of the magnetic flux oriented in the +Z-direction, is positive. The magnetic flux that has a shorter path through the interior of magnetically free layer 45 is therefore believed to affect the magnetization of magnetically free layer 45. In FIG. 6A, the path length difference D1 is shown as a distance in the Z-direction for the convenience of explanation, but the path length difference D1 may also be a difference in the length along the path of the magnetic flux.

FIG. 6B illustrates, of magnet flux that enters and exits first magnetically pinned layer 43, magnetic flux that has a long path. Both the magnetic flux that leaves top part 43A of first magnetically pinned layer 43 and the magnetic flux that leaves bottom part 43B of first magnetically pinned layer 43 may pass through nonmagnetic layer 44, enter magnetically free layer 45, pass through nonmagnetic layer 44 again, and then return to first magnetically pinned layer 43. In the example shown in FIG. 6B, there is little difference between the path length difference D2 of the magnetic flux that leaves top part 43A (the difference between the path length of the magnetic flux oriented in the −Z-direction and the path length of the magnetic flux oriented in the +Z-direction) and the path length difference D3 of the magnetic flux that leaves bottom part 43B. As a result, in the case of the magnetic flux that has a long path, the influence upon the magnetization of magnetically free layer 45 exerted by the magnetic flux that passes through the interior of magnetically free layer 45 is considered to be small. Considering the magnetic flux that has a short path illustrated in FIG. 6A and the magnetic flux that has a long path illustrated in FIG. 6B, the magnetic flux that has a short path is thought to have a greater effect upon the magnetization of magnetically free layer 45 as a whole. In other words, due to the contribution of the magnetic flux that has a short path, first magnetically pinned layer 43 is believed to cause cancelling magnetic field Hin that is oriented in the direction opposite to the magnetization direction of first magnetically pinned layer 43 to be applied to magnetically free layer 45.

In view of the above, a large number of convex portions and concave portions of center line 44A of nonmagnetic layer 44 is believed to produce a large amount of magnetic flux that passes through magnetically free layer 45, resulting in the ability to obtain a relatively strong cancelling magnetic field Hin. As can be understood from FIG. 6A, if both sides of each top part of centerline 44A drop sharply in the −Z-direction, that is, if the convex portions are steep, the path length differences D1 are believed to be great. Considering these factors, the number of convex portions (density of convex portions) within a certain interval (e.g., within an interval having a certain length in the X-direction) is thought to affect cancelling magnetic field Hin. For example, if center line 44A has a shape having a large number of convex portions within a certain interval (having a high density of convex portions), cancelling magnetic field Hin is believed to be relatively strong. In some cases, the shape of the convex portions is also believed to also affect cancelling magnetic field Hin. For example, if the convex portions in centerline 44A are formed with a steep shape (steeply depressed on both sides of the top parts), cancelling magnetic field Hin is believed to be stronger than if the convex portions have a gentle form.

As can be understood from FIG. 6A-6B, the strength of cancelling magnetic field Hin can be adjusted by concavo-convex shape 46 of nonmagnetic layer 44. Concavo-convex shape 46 of nonmagnetic layer 44 can be formed by various methods. For example, the surface of the layer below nonmagnetic layer 44 in the direction of stacking (e.g., first magnetically pinned layer 43) can be etched before nonmagnetic layer 44 is formed. The etching of the lower layer may increase the unevenness of the lower layer. Because the surface roughness and surface shape of the lower layer is reflected to some extent in nonmagnetic layer 44, the surface of nonmagnetic layer 44 may also become rougher and more uneven. The longer the etching time, the more uneven the lower layer becomes, and accordingly, the more uneven nonmagnetic layer 44 may become. Another method is to heat (anneal) the lower layer at a high temperature. The higher the heating temperature or the longer the heating time, the more uneven the lower layer becomes, and nonmagnetic layer 44 may accordingly become more uneven. Heating (annealing) may be performed after nonmagnetic layer 44 is formed. Another method is to form a layer of material (such as Ru, Mn, or alloys containing Mn) whose surface tends to become rougher due to the growth of crystal grains below nonmagnetic layer 44 in the direction of stacking. The thicker this layer is, the more uneven the layer becomes, and nonmagnetic layer 44 may accordingly become more uneven.

### Method for Quantifying the Concavo-Convex Shape 46 of Centerline 44A of Magnetic Layer 44

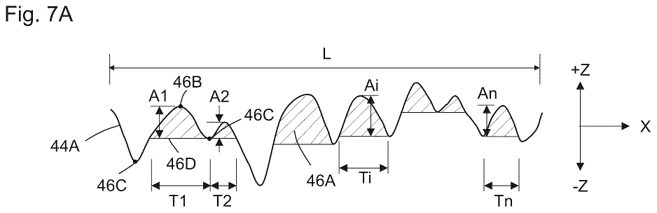

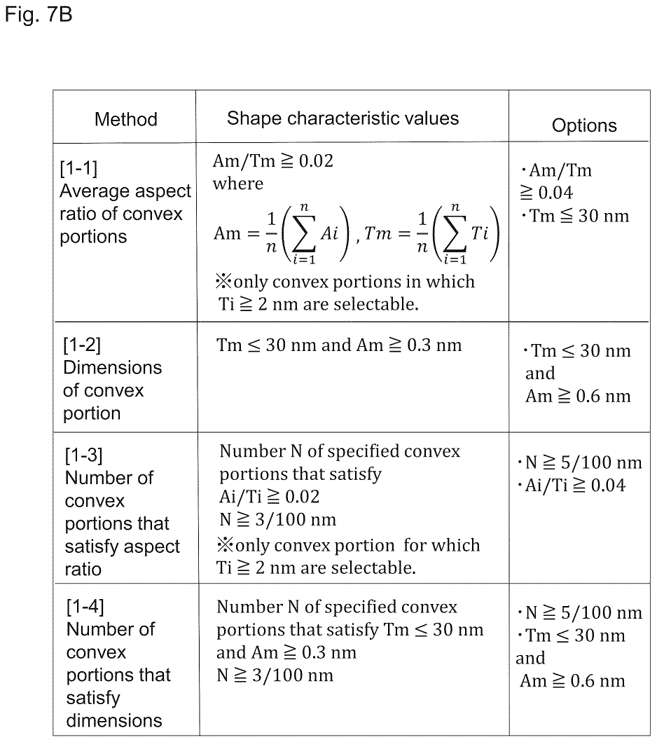

Explanation next regards the method of quantifying concavo-convex shape 46 of centerline 44A of nonmagnetic layer 44, i.e., the method of finding the appropriate shape characteristic values of concavo-convex shape 46. In this way, the shape of concavo-convex shape 46 can be better defined. The shape characteristic values may be obtained for the portion of centerline 44A that is included in target range L (see FIGS. 7A, 8A, 9A, and 10A). The length in the X-direction of target range L may be, for example, at least 100 nm, and may be the diameter of, or about half the diameter of, non-magnetic layer 44 as viewed from the Z-direction.

In a first method, as a pre-process for quantification, filter processing can be applied to centerline 44A obtained by TEM observation. Specifically, for example, in order to remove short-wavelength minute unevenness components from centerline 44A shown in FIG. 5, filter processing deletes components of wavelength λs or less. No particular limitation applies to wavelength λs, but in this example embodiment, for example, wavelength λs can be 1 nm. Minute unevenness components are components that may cause errors in obtaining appropriate shape characteristic values. Removing the minute unevenness components may suppress these errors. Although not required, components having wavelength λc or longer may be cut by filter processing to remove the long-wavelength undulation components of center line 44A. In this case, the filter processing extracts wavelength components having wavelengths greater than λs but less than λc from centerline 44A shown in FIG. 5. The undulation component may also be a component that can cause errors. Therefore, although not required, removing the undulation component provides greater suppression of errors. FIG. 7A shows filtered centerline 44a compressed in the X-direction.

The first method focuses on convex portions 46A that are parts of concavo-convex shape 46 and that protrude toward magnetically free layer 45. Each convex portion 46A is defined, in this case, by base 46D and by top part 46B that protrudes toward magnetically free layer 45. Base 46D may be a line extending in a direction (the X-direction) perpendicular to the Z-direction from bottom part 46C that, of two bottom parts 46C adjacent to top part 46B on either side of top part 46B, is closer to top part 46B in the Z-direction. One end of base 46D may be at bottom part 46C that is closer to top part 46B in the Z-direction, and the other end may be at the point where a line drawn in the X-direction from bottom part 46C that is closer to top 46B intersects with centerline 44A between top part 46B and the other bottom part 46C. FIG. 7A shows in hatching convex portions 46A defined by this description.

FIG. 7B shows several methods for determining the appropriate shape characteristic values of concavo-convex shape 46 of centerline 44A of nonmagnetic layer 44. For each of the n extracted convex portions 46A, lengths T1, T2, . . . , Ti, . . . , Tn of base 46D and heights A1, A2, . . . , Ai, . . . , An of convex portions 46A (the distance in the Z-direction between base 46D and top part 46B) may be obtained from TEM images. Next, average length Tm of base 46D of convex portions 46A may be obtained as (T1+T2+. . . +Tn)/n, and average height Am of the convex portions 46A may be obtained as (A1+A2+. . . +An)/n. In this case, for example, to exclude minute convex portions 46A, only convex portions 46A in which Ti≥2 nm can be selected to obtain average length Tm and average height Am. The widths of the minute convex portions to be excluded are not limited to the above, and a larger value (e.g., 3 nm or more) or a smaller value (e.g., 0.5 nm or more, or 1 nm or more) may be selected as appropriate.

As described above, convex portions 46A having steeper shapes are considered to contribute more to cancelling magnetic field Hin than convex portions having a nearly flat shape. The shape of concavo-convex shape 46 can therefore be specified, for example, by the average aspect ratio of convex portions 46A (Method 1-1). In this case, the average aspect ratio can be defined as Am/Tm≥0.02, and also as Am/Tm≥0.04. There is no restriction on Tm. For example, by excluding the above-mentioned minute convex portions, average length Tm may be substantially defined as Tm≥2 nm. If relatively large convex portions 46A are selected, Tm will be relatively large. (e.g., Tm≥10 nm). If there is a large number of larger convex portions 46A, the number (density) of convex portions 46A per unit length in the X-direction may decrease. Because it is thought that a larger number of convex portions 46A of a certain size may generate larger cancelling magnetic field Hin, average length Tm may be defined as Tm≤30 nm. The shape of concavo-convex shape 46 may be specified by the dimensions of Am and Tm (Method 1-2). In this case, dimensions may be defined as Tm≤30 nm and Am≥0.3 nm, or may be defined as Tm≤30 nm and Am≥0.6 nm.

The shape of concavo-convex shape 46 may be specified by the number of specified convex portions per unit interval in the X-direction (Method 1-3). The specified convex portions can be convex portions 46A in which Ai/Ti≥0.02 or Ai/Ti≥0.04. To exclude minute convex portions 46A, only convex portions 46A in which Ti≥2 nm can be selected as the specified convex portions. The X-direction unit interval may be, for example, an interval of length of 100 nm selected from target range L, but is not limited to 100 nm. The number N of the specified convex portions for each interval of 100 nm can be more than 3 or more than 5. The specified convex portions can be defined as convex portions 46A in which Ti≤30 nm and Ai≥0.3 nm (Method 1-4). Alternatively, the specified convex portions can be defined as convex portions 46A in which T≤30 nm and A≥0.6 nm.

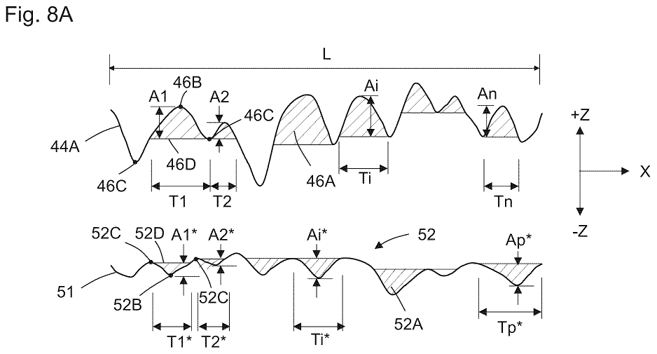

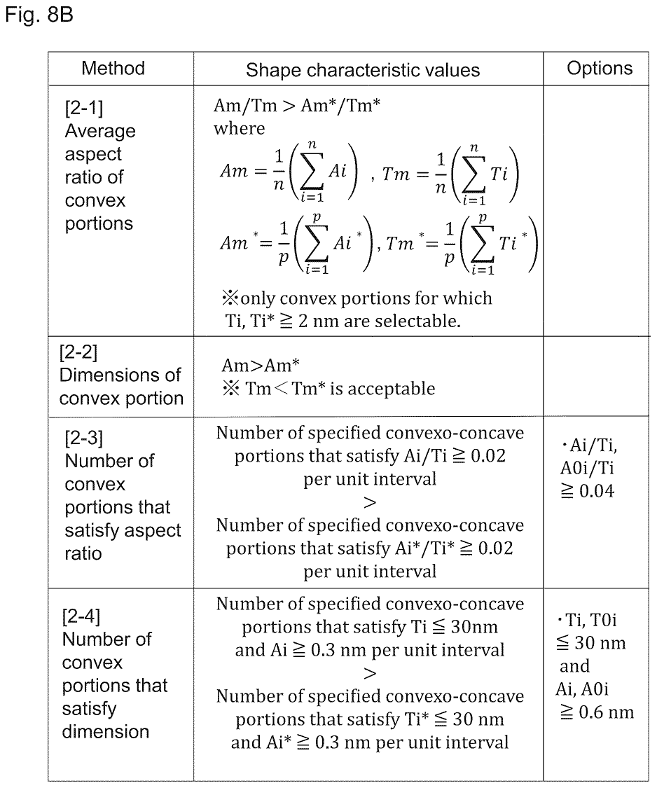

FIG. 8A-8B show a second method for determining the appropriate shape characteristic values of concavo-convex shape 46 of centerline 44A of nonmagnetic layer 44. In a cross section parallel to the Z-direction, concavo-convex shape 46 of centerline 44A of nonmagnetic layer 44 may be formed to be, for example, rougher than concavo-convex shape 52 of first electrode layer 5 (electrode boundary line 51 shown in FIG. 2) that faces substrate 2. Therefore, in the second method, the roughness of concavo-convex shape 46 may be specified compared to the roughness of concavo-convex shape 52 of electrode boundary line 51. FIG. 8A shows, in a compressed state in the X-direction, centerline 44A and electrode boundary line 51 that have been filtered in the same way as in Method 1. Concavo-convex shape 46 of centerline 44A may have first convex portions 46A. First convex portions 46A may be defined in the same manner as convex portions 46A in Method 1. Concavo-convex shape 52 of electrode boundary line 51 may have second convex portions 52A protruding toward substrate 2. Each second convex portion 52A may be defined by top part 52B and base 52D similarly to first convex portions 46A. Base 52D may be a line extending in the direction (the X-direction) perpendicular to the Z-direction from, of two bottom parts 52C adjacent to top part 52B on either side of top part 52B, bottom part 52C that is closer to top part 52B in the Z-direction. One end of base 52D may be at bottom part 52C that is closer to top part 52B in the Z-direction, and the other end may be at the point where a line drawn in the X-direction from bottom part 46C that is closer to top 52B intersects with electrode boundary line 51 between top part 52B and the other bottom part 52C. FIG. 8A shows in hatching first convex portions 46A and second convex portions 52A.

FIG. 8B shows several methods for determining the shape characteristic values of concavo-convex shape 46 of centerline 44A of nonmagnetic layer 44. According to method 2-1, if the average length of bases 46D of first convex portions 46A is Tm, the average height of first convex portions 46A (the average distance in the Z-direction between base 46D and top part 46B) is Am, the average length of bases 52D of second convex portions 52A is Tm*, and the average height of second convex portions 52A (the average distance in the Z-direction between bases 52D and top parts 52B) is Am*, then Am/Tm>Am*/ Tm*. According to Method 2-2, Am>Am*. In this case, the average lengths may be defined as Tm<Tm* to increase the density of convex portions in concavo-convex shape 46. In these methods, to exclude minute convex portions 46A and 52A, only convex portions 46A in which Ti≥2 nm and convex portions 52A in which Ti*≥2 nm can be selected to obtain average lengths Tm and Tm* and average heights Am and Am*.

The shape of concavo-convex shape 46 can also be defined by the relationship of the number of specified convex portions for each unit interval in the X-direction. According to Method 2-3, when the length of bases 46D of first convex portions 46A is Ti, the height of first convex portions 46A (the distance in the Z-direction between bases 46D and top parts 46B) is Ai, the length of bases 52D of second convex portions 52A is Ti*, and the height of second convex portions 52A (the distance in the Z-direction between bases 52D and top parts 52B) is Ai*, then the number of first convex portions 46A (specified convex portions) in which Ai/Ti≥0.02 per unit length section in the X-direction may be larger than the number of second convex portions 52A (specified convex portions) in which Ai*/Ti*≥0.02 per unit length section in the X-direction. According to method 2-4, the number per unit length interval in the X-direction of first convex portions 46A (specified convex portions) in which Ti≤30 and Ai≥0.3 nm may be larger than the number per unit length interval in the X-direction of second convex portions 52A (specified convex portions) in which Ti*≤30 and Ai*≥0.3 nm. In these methods, the X-direction unit interval may be, for example, an interval having a length of 100 nm selected from target range L, but is not limited to 100 nm. The aspect ratio may be 0.04 instead of 0.02. Alternatively, Ti and Ti* may be 30 nm or less and Ai and Ai* may be 0.6 nm or more.

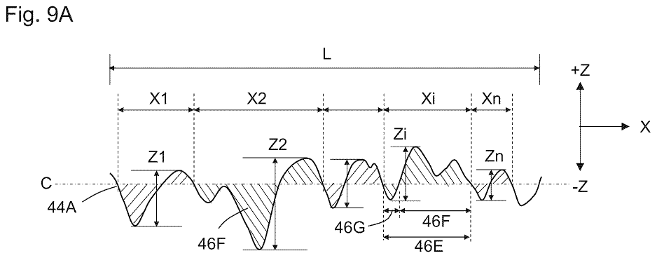

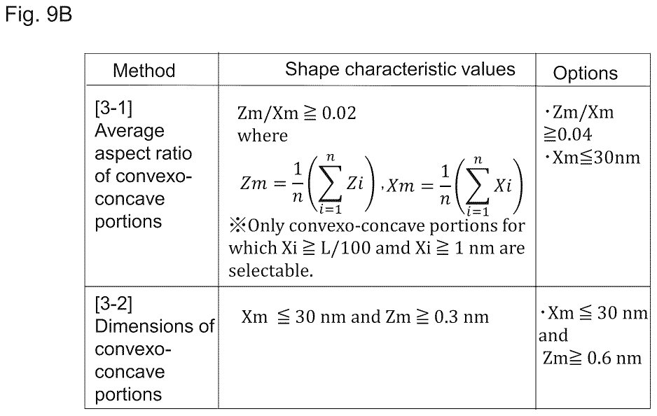

FIG. 9A-9B show a third method for determining the appropriate shape characteristic values for concavo-convex shape 46 of centerline 44A of nonmagnetic layer 44. FIG. 9A shows centerline 44A in a compressed state in the X-direction. The third method focuses on concavo-convex portions 46E that belong to concavo-convex shape 46. To obtain concavo-convex portions 46E, centerline C of concavo-convex shape 46 may first be obtained. One continuous upper portion of concavo-convex shape 46 divided by centerline C may be ridges 46F and one continuous lower portion may be valley 46G. Concavo-convex portion 46E may be a region comprising a pair of adjacent ridges 46F and valley 46G. As centerline C, for example, the average line specified in JIS B 0601-2001 may be used. In this case, centerline C can be obtained, for example, by the least-squares method after considering concavo-convex shape 46 as a curve (a cross-sectional curve at a certain position of nonmagnetic layer 44).

FIG. 9B shows several methods for determining the appropriate shape characteristic values of concavo-convex shape 46 of centerline 44A of nonmagnetic layer 44. According to method 3-1, for each of the n extracted concavo-convex portions 46E, lengths X1, X2, . . . , Xi, . . . , Xn of concavo-convex portions 46E (dimensions in the X-direction) and heights Z1, Z2, . . . , Zi, . . . , Zn of concavo-convex portions 46E (dimensions in the Z-direction) may be obtained from TEM images. The height of concavo-convex portions 46E is the Z-direction distance between the points of concavo-convex portions 46E that are closest to magnetically free layer 45 and the points that are farthest away from magnetically free layer 45 in the Z-direction. Next, average length Xm of concavo-convex portions 46E may be obtained as (X1+X2+. . . +Xn)/n, and average height Zm of concavo-convex portions 46E may be obtained as (Z1+Z2+. . . +Zn)/n. In this case, for example, minute concavo-convex portions 46E may be excluded. For example, concavo-convex portions 46E whose length is less than a specific percentage (e.g., less than 1%) of target range L may be excluded. For example, concavo-convex portions 46E whose height is less than a specific percentage (e.g., less than 10%) of the maximum height of concavo-convex portions 46E in target range L may be excluded. In FIG. 9A, concavo-convex portions 46H whose length is less than 1% of the length of target range L may be excluded. In this example embodiment, the filter processing of the first and second methods may be omitted. However, if target range L is broad, relatively large concavo-convex portions 46E may be excluded, and as a result, only concavo-convex portions 46E whose length is less than 1% of target range L and less than 1 nm may be excluded. Convex portions 46A having a steep shape are considered to contribute more to cancelling magnetic field Hin than convex portions 46A having a nearly flat shape. Therefore, the dimensions of convex portions 46A may be Zm/Xm≥0.02 or Zm/Xm≥0.04. For the same reasons as in Method 1, the dimension may be defined as Xm≤30 nm. Concavo-convex shape 46 can also be specified by the dimensions of Zm and Xm (Method 3-2). In this case, the dimensions may be defined as Xm≤30 nm and Zm≥0.3 nm, or may be defined as Xm≤30 nm and Zm≥0.6 nm.

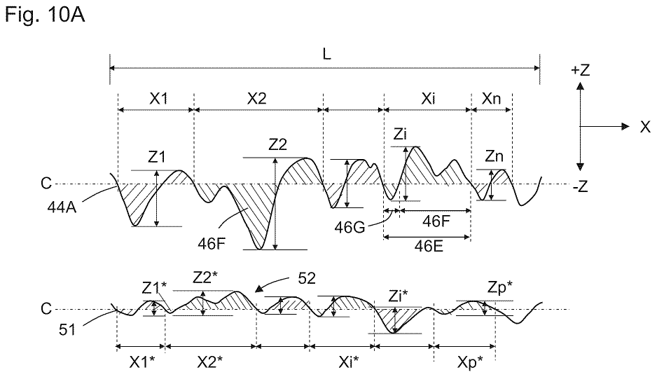

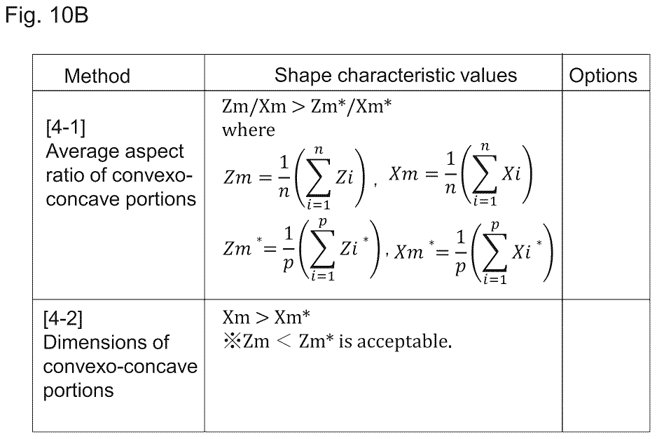

FIG. 10A-10B show a fourth method for determining the appropriate shape characteristic values for concavo-convex shape 46 of centerline 44A of nonmagnetic layer 44. FIG. 10A shows centerline 44A in a compressed state in the X-direction. In the fourth method, the roughness of concavo-convex shape 46 of centerline 44A may be defined compared to electrode boundary line 51 of first electrode layer 5. Concavo-convex shape 46 of centerline 44A may have first concavo-convex portions 46E. First concavo-convex portions 46E are the same as concavo-convex portions 46E in Method 3 and may be defined in the same manner as concavo-convex portions 46E. Electrode boundary line 51 may have second concavo-convex portions 52E each comprising a pair of ridges and a valley adjacent to each other. Second concavo-convex portions 52E may be defined in the same manner as first concavo-convex portions 46E.

FIG. 10B shows several methods for determining appropriate shape characteristic values for concavo-convex shape 46 of centerline 44A of nonmagnetic layer 44. According to method 4-1, if the average length in the X-direction of first concavo-convex portions 46E is Xm, the average height in the Z-direction of first concavo-convex portions 46E is Zm, the average length in the X-direction of second concavo-convex portions 52E is Xm*, and the average height in the Z-direction of the plurality of second concavo-convex shapes 52E is Zm*, then the average height in the Z-direction of second concavo-convex portions 46E is Zm*, and Zm/Xm>Zm*/Xm*. According to Method 4-2, Zm>Zm*. In order to increase the density of convex portions in concavo-convex shape 46, the dimensions may be defined as Xm<Xm*.

### Method for Manufacturing Magnetoresistive Element 3 and Magnetic Sensor 1

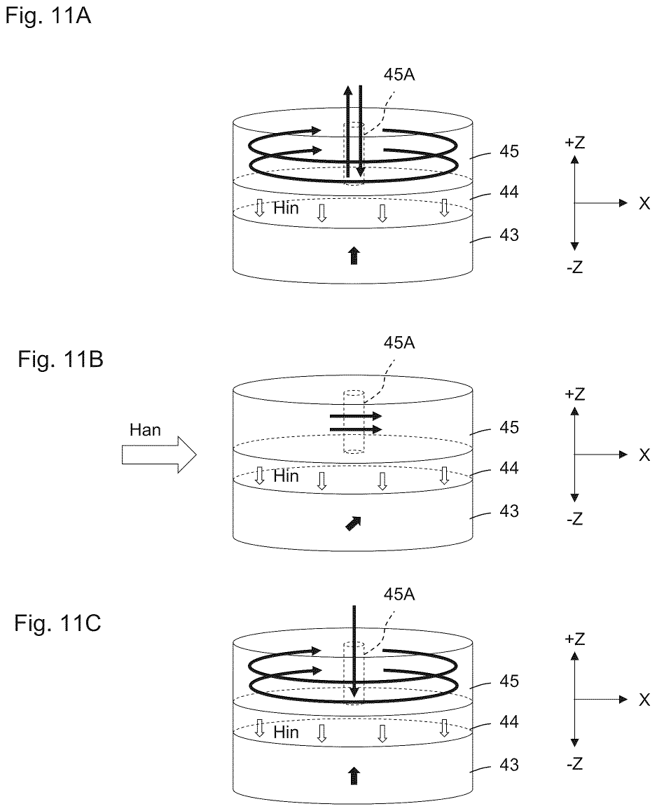

Referring to FIG. 11A-11C, a method for manufacturing magnetoresistive element 3 is next described. The arrows indicate the magnetization directions or the direction of magnetic fields. First, as shown in FIG. 11A, first electrode layer 5, magnetic field detector 4, and second electrode layer 6 may be formed sequentially in the +Z-direction. FIGS. 11A-11C show only first magnetically pinned layer 43, nonmagnetic layer 44 and magnetically free layer 45. In the example shown in FIG. 11A, first magnetically pinned layer 43, nonmagnetic layer 44, and magnetically free layer 45 are formed in that order, but the layers may also be formed in the order of magnetically free layer 45, nonmagnetic layer 44, and first magnetically pinned layer 43. At this stage, magnetically free layer 45 may be magnetized in a vortex shape in a plane perpendicular to the Z-direction. Whether the magnetization direction of core 45A of magnetically free layer 45 is oriented in the +Z-direction or oriented in the −Z direction is randomly determined (as indicated by the two arrows in different directions on core 45A). However, once the magnetization direction of core 45A is oriented in the +Z-direction or oriented in the −Z direction, the magnetization direction may be stabilized. Next, first magnetically pinned layer 43 is magnetized in the Z-direction to fix the magnetization direction of first magnetically pinned layer 43 in the Z-direction (the +Z direction in the examples in FIGS. 11A to 11C). This magnetization generates cancelling magnetic field Hin, but the magnetic field strength of cancelling magnetic field Hin is weak and does not affect the magnetization direction of core 45A of magnetically free layer 45.

Next, as shown in FIG. 11B, a vortex dissipating magnetic field Han in the X-direction is applied to magnetic field detector 4 (magnetically free layer 45). Vortex dissipating magnetic field Han may have a magnetic field strength that causes the vortex magnetization of magnetically free layer 45 to disappear, whereby magnetically free layer 45 is magnetized entirely in the X-direction. The magnetization direction of first magnetically pinned layer 43 is also tilted in the X-direction. The direction of the vortex dissipating magnetic field Han is not limited to the X-direction but may be any direction other than the Z-direction (the first direction) and may be a direction orthogonal to the Z-direction that is different from the illustrated X-direction.

Next, as shown in FIG. 11C, the application of vortex dissipating magnetic field Han is stopped, whereby magnetically free layer 45 is caused to be magnetized again in a vortex shape in a plane perpendicular to the Z-direction. However, first magnetically pinned layer 43 applies a magnetic field to magnetically free layer 45 in the direction opposite to the magnetization direction of first magnetically pinned layer 43. When the vortex dissipating magnetic field Han disappears, a magnetic field applied to magnetically free layer 45 other than vortex dissipating magnetic field Han determines the magnetization direction of core 45A, and because this magnetic field may be a minute magnetic field, the strength of cancelling magnetic field Hin is sufficient to determine the magnetization direction of core 45A. Therefore, cancelling magnetic field Hin causes the magnetization direction of core 45A of magnetically free layer 45 to be oriented in the same direction as cancelling magnetic field Hin. Cancelling magnetic field Hin is oriented in the direction opposite to the magnetization direction of first magnetically pinned layer 43, and the magnetization direction of core 45A is therefore also oriented in the direction opposite to the magnetization direction of the first magnetically pinned layer 43. The magnetization direction of first magnetically pinned layer 43 can be determined by a magnetizing process, and as a result, the magnetization direction of core 45A of magnetically free layer 45 can be intentionally determined. The magnetization direction of first magnetically pinned layer 43 is again oriented in the Z-direction. Applying vortex dissipating magnetic field Han and then stopping it can be performed in the wafer process, but the timing is not limited as long as the process is performed before magnetic sensor 1 is shipped.

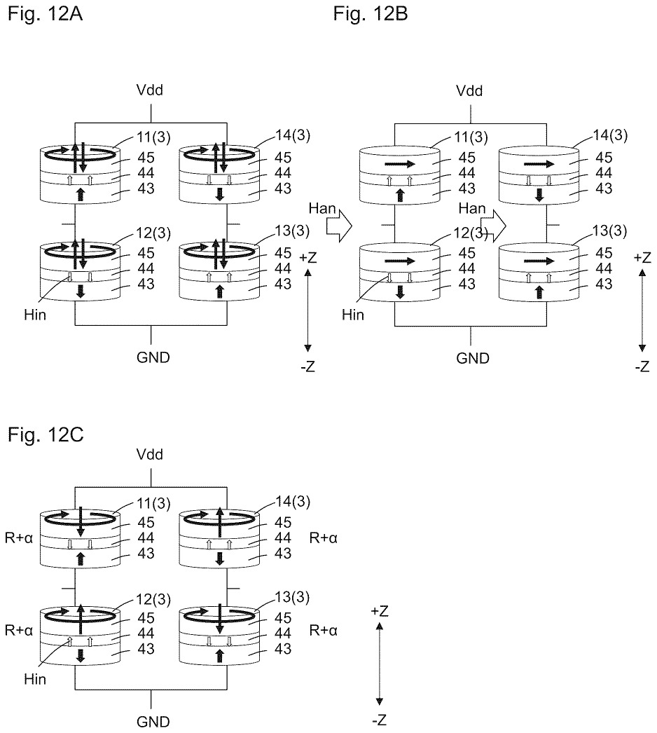

A method of manufacturing magnetic sensor 1 is next described. For the convenience of explanation, first through fourth element units 11-14 are assumed to each comprise one magnetoresistive element 3. First, as shown in FIG. 12A, first through fourth element units 11-14 may be formed and differential circuit 17 (not shown) may also be formed. These processes are carried out in the wafer process and can therefore be carried out simultaneously. However, these processes can also be carried out separately, and no limitation is imposed on the timing of implementation. Next, first magnetically pinned layers 43 of magnetoresistive elements 3 of first through fourth element units 11-14 may be magnetized. Specifically, a magnetic field in the +Z-direction (or the −Z-direction) may be applied to first and fourth element units 11 and 14 while first and fourth element units 11 and 14 are locally heated with a laser beam. Similarly, a magnetic field in the −Z-direction (or the +Z-direction) may be applied to second and third element units 12 and 13 while second and third element units 12 and 13 are locally heated by a laser beam. The magnetization directions of first magnetically pinned layers 43 of first and fourth element units 11 and 14 and the magnetization directions of first magnetically pinned layers 43 of second and third element units 12 and 13 are opposite each other. The magnetization directions of cores 45A of magnetically free layers 45 may be randomly determined.

Next, the magnetization directions of cores 45A of magnetically free layers 45 of first to fourth element units 11-14 may be determined in accordance with the method for manufacturing magnetoresistive element 3 described above. The actual processes are described above, and details are therefore here omitted. First, as shown in FIG. 12B, vortex dissipating magnetic field Han may be applied to first to fourth element units 11-14 to eliminate the vortex-shaped magnetizations of magnetically free layers 45 of first to fourth element units 11-14. Next, as shown in FIG. 12C, the application of vortex dissipating magnetic field Han may be stopped. Magnetically free layer 45 may then be magnetized in the direction opposite to corresponding first magnetically pinned layer 43, whereby the magnetization direction of cores 45A of all magnetically free layers 45 may be intentionally determined.

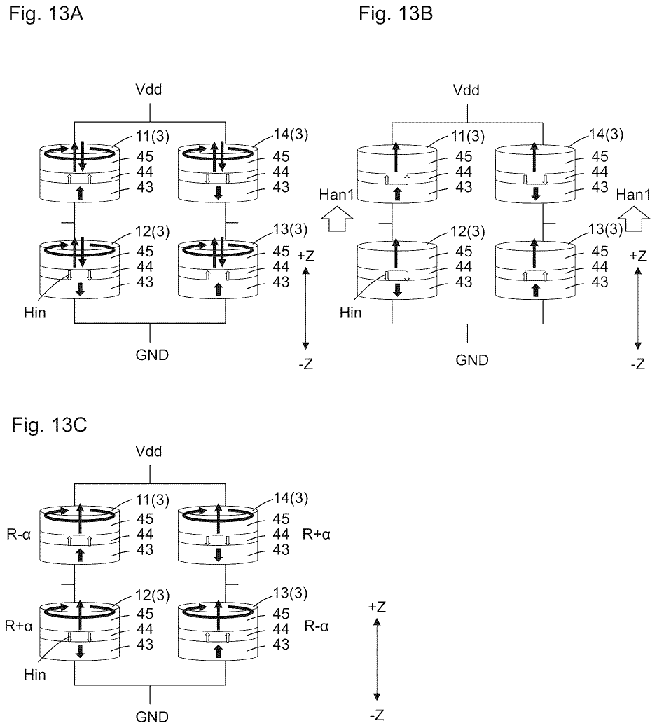

FIG. 13A-13C are similar to FIG. 12A-12C showing the method for manufacturing the magnetic sensor in the comparative example. First, as shown in FIG. 13A, first through fourth element units 11-14 and the differential circuit 17 (not shown) may be formed, and first magnetically pinned layers 43 of first to fourth element units 11-14 may be magnetized. These processes can be performed in the same manner as in FIG. 12A. Next, as shown in FIG. 13B, vortex dissipating magnetic field Han1 may be applied in the +Z-direction. This causes the magnetization directions of cores 45A of magnetically free layers 45 to be oriented in the +Z-direction. In this state, the application of vortex dissipating magnetic field Han1 may be stopped. The application of vortex dissipating magnetic field Han1 may be stopped when the magnetization direction of core 45A is oriented in the +Z-direction, and as a result, the magnetization directions of cores 45A of magnetically free layers 45 remains oriented in the +Z-direction. Therefore, the magnetization directions of cores 45A of all magnetically free layers 45 can be intentionally determined even in the comparative example.

Cancelling magnetic field Hin may also be generated in the comparative example. However, in the comparative example, the application of vortex dissipating magnetic field Han1 may cause the magnetization directions of cores 45A to be oriented in the +Z-direction and to become stabilized in this state. As a result, cancelling magnetic field Hin may have no effect on the magnetization directions of cores 45A when the application of vortex dissipating magnetic field Han1 is stopped. In the present example embodiment, the magnetization states of cores 45A may become temporarily unstable when the application of vortex dissipating magnetic field Han is stopped, and the magnetization direction of cores 45A may therefore be determined by cancelling magnetic field Hin. The mechanism for determining the magnetization directions of cores 45A in this example embodiment is therefore different from that of the comparative example.

The comparative example also results in an offset of the magnetic sensor output. In the interest of simplifying the explanation, all resistances of first through fourth element units 11-14 are regarded as R in an unmagnetized state (assuming no vortex-shaped magnetization) and a zero magnetic field state, and the offset in resistance caused by the vortex-shaped magnetization of magnetically free layers 45 is regarded as α. As shown in FIG. 13C, in the comparative example, the magnetization directions of all magnetically free layers 45 of first through fourth element units 11-14 are on the whole oriented in the +Z-direction. In first and third element units 11 and 13, the magnetization directions of cores 45A of magnetically free layers 45 and the magnetization directions of first magnetically pinned layers 43 are oriented in the same direction. In second and fourth element units 12 and 14, the magnetization direction of cores 45A of magnetically free layers 45 and the magnetization directions of first magnetically pinned layers 43 are oriented in opposite directions. As a result, the resistance in a zero magnetic field state of first and third element units 11 and 13 is R−α, while the resistance in a zero magnetic field state of second and fourth element units 12 and 14 is R+α. If V1=Vdd×(R+α)/(2R) and V2=Vdd×(R−α)/(2R), then V1−V2=α/R. Therefore, the offset of output is caused by the vortex-shaped magnetization of magnetically free layers 45.

In contrast, as shown in FIG. 12C, the magnetization direction of cores 45A and the magnetization direction of first magnetically pinned layers 43 are oriented in opposite directions in all element units 11-14 in this example embodiment, and as a result, the resistance in a zero magnetic field state may be R+α. In other words, V1=V2=Vdd×(R+α)/(2R+2α), and V1−V2=0. Therefore, output offset arising from vortex-shaped magnetization in magnetically free layers 45 may not occur.

In the comparative example, vortex dissipating magnetic field Han1 in the Z-direction reverses the magnetization directions of cores 45A of magnetically free layers 45 that are in a stable state, and this generally requires a considerable amount of strength. As a result, the magnetization directions of first magnetically pinned layers 43 may also be reversed. If the magnetization directions of first magnetically pinned layers 43 of second and fourth element units 12 and 14 in FIGS. 13B and 13C should be reversed in the +Z-direction, the magnetization directions of first magnetically pinned layers 43 of all element units 11-14 may orient in the +Z-direction and will not function as a magnetic sensor. The magnetization direction of first magnetically pinned layers 43 that have once been reversed may possibly be restored by adding an antiferromagnetic layer, but this remedy may result in an increase in cost.

### Variation

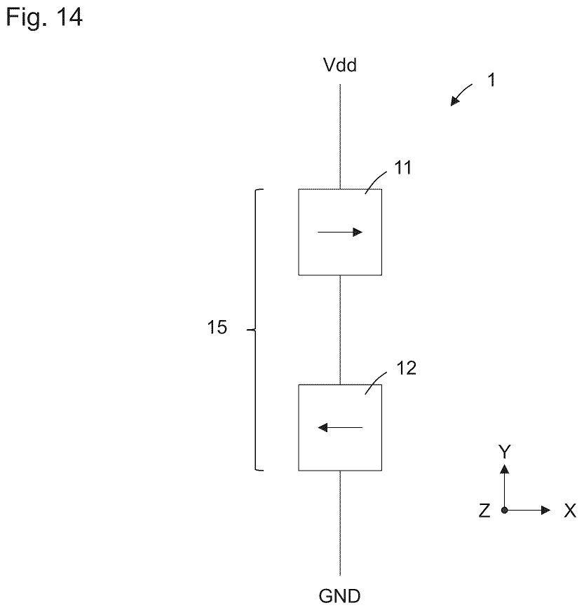

The present disclosure is not limited to the above-described example embodiments. Magnetic sensor 1 may be a half-bridge structure. FIG. 14 is a schematic view showing the structure of magnetic sensor 1 according to a variation. In magnetic sensor 1 of the variation, element units may comprise only first and second element units 11 and 12. Each of first and second element units 11 and 12 may comprise at least one magnetoresistive element 3 described above. First and second element units 11 and 12 may be connected in series to form first group 15, and one end of first group 15 may be connected to the power supply Vdd and the other end may be grounded. The magnetization direction of first magnetically pinned layer 43 of first element unit 11 and the magnetization direction of first magnetically pinned layer 43 of second element unit 12 may be opposite to each other. Magnetic sensor 1 of this variation can be made in the same way as first and second element units 11 and 12 (full bridge structure) of magnetic sensor 1 of the above-described example embodiment.

The present disclosure provides a magnetic sensor comprising magnetoresistive elements, wherein each magnetoresistive element has a magnetically free layer magnetized in a vortex shape in a zero magnetic field state and a magnetically pinned layer whose magnetization direction is fixed in the film thickness direction, and wherein the magnetization direction of the center of the vortex shape in each magnetically free layer is controlled in the absence of an external magnetic field.

The technology according to the present disclosure has been explained with reference to the above example embodiments. The technology according to the present disclosure is not limited to the specific examples described above, and various aspects and variations of the technology according to the present disclosure can be implemented based on the above description.

### EXPLANATION OF REFERENCE NUMERALS

1 magnetic sensor
2 substrate
3 magnetoresistive element
4 magnetic field detector
5, 6 first and second electrode layers
11-14 first through fourth element units
43 first magnetically pinned layer (magnetically pinned layer)
44 nonmagnetic layer
45 magnetically free layer
46 concavo-convex shape
Z first direction

1. A magnetic sensor comprising element units, each of which comprises at least one magnetoresistive element, wherein
the element units comprise a first element unit and a second element unit,
the first element unit and the second element unit are connected in series to form a first group,
one end of the first group is connected to a power supply and an other end is grounded,
the first element unit is located on the side of the power supply, and the second element unit is located on the grounded side,
each magnetoresistive element has a magnetically free layer, a magnetically pinned layer, and a nonmagnetic layer arranged in a first direction,
the nonmagnetic layer is located between the magnetically free layer and the magnetically pinned layer,
a magnetization direction of the magnetically pinned layer of at least one magnetoresistive element included in the first element unit and a magnetization direction of the magnetically pinned layer of at least one magnetoresistive element included in the second element unit are oriented in opposite directions in the first direction,
in each magnetoresistive element, the magnetically free layer is magnetized in a vortex shape in a plane perpendicular to the first direction in an absence of an external magnetic field,
a magnetization direction of the magnetically free layer is variable in accordance with an external magnetic field, and
a magnetization direction of a center of the vortex shape of the magnetically free layer is oriented in the first direction and is oriented in the direction opposite to the magnetization direction of the magnetically pinned layer in the absence of an external magnetic field.

2. The magnetic sensor according to claim 1, wherein at least a part of a centerline of the nonmagnetic layer has a concavo-convex shape in a cross section parallel to the first direction.

3. The magnetic sensor according to claim 1, wherein the magnetically pinned layer applies, through the nonmagnetic layer, a magnetic field to the magnetically free layer in the direction opposite to the magnetization direction of the magnetically pinned layer.

4. The magnetic sensor according to claim 1, wherein
the element units comprise a third element unit and a fourth element unit,
the third element unit and the fourth element unit are connected in series to form a second group,
one end of the second group is connected to the power supply and an other end is grounded,
the fourth element unit is located on the side of the power supply, and the third element unit is located on the grounded side,
the differential circuit is provided to determine a difference between an output that is between the first element unit and the second element unit and an other output that is between the third element unit and the fourth element unit, and
a magnetization direction of the magnetically pinned layers of at least one magnetoresistive element included in each of the first and third element units and a magnetization direction of the magnetically pinned layers of at least one magnetoresistive element included in each of the second and fourth element units are opposite to each other.

5. The magnetic sensor according to claim 1, wherein the nonmagnetic layers comprise an insulating layer.

6. A magnetic sensor comprising element units, each of which comprises at least one magnetoresistive element, wherein
the element units comprise a first element unit and a second element unit,
the first element unit and the second element unit are connected in series to form a first group,
one end of the first group is connected to a power supply and an other end is grounded,
the first element unit is located on the side of the power supply, and the second element unit is located on the grounded side,
each magnetoresistive element has a magnetically free layer, a magnetically pinned layer, and a nonmagnetic layer arranged in a first direction,
the nonmagnetic layer is located between the magnetically free layer and the magnetically pinned layer,
a magnetization direction of the magnetically pinned layer of at least one magnetoresistive element included in the first element unit and a magnetization direction of the magnetically pinned layer of at least one magnetoresistive element included in the second element unit are oriented in opposite directions in the first direction,
in each magnetoresistive element, the magnetically free layer is magnetized in a vortex shape in a plane perpendicular to the first direction in an absence of an external magnetic field,
a magnetization direction of the magnetically free layer is variable in accordance with an external magnetic field, and
at least a part of a centerline of the nonmagnetic layer has a concavo-convex shape in a cross section parallel to the first direction.

7. The magnetic sensor according to claim 6, wherein, in each magnetoresistive element, a magnetization direction of a center of the vortex shape of the magnetically free layer is oriented in the first direction and is oriented in the direction opposite to the magnetization direction of the magnetically pinned layer in an absence of an external magnetic field.

8. The magnetic sensor according to claim 6, wherein the magnetically pinned layer applies, through the nonmagnetic layer, a magnetic field to the magnetically free layer in the direction opposite to the magnetization direction of the magnetically pinned layer.

9. The magnetic sensor according to claim 6, wherein
the element units comprise a third element unit and a fourth element unit,
the third element unit and the fourth element unit are connected in series to form a second group,
one end of the second group is connected to the power supply and an other end is grounded,
the fourth element unit is located on the side of the power supply, and the third element unit is located on the grounded side,
a differential circuit is provided to determine a difference between an output that is between the first element unit and the second element unit and an output that is between the third element unit and the fourth element unit, and
a magnetization direction of the magnetically pinned layers of at least one magnetoresistive element included in each of the first and third element units and a magnetization direction of the magnetically pinned layers of at least one magnetoresistive element included in each of the second and fourth element units are opposite to each other.

10. The magnetic sensor according to claim 6, wherein the nonmagnetic layer comprises an insulating layer.

11. A method for manufacturing a magnetoresistive element comprising steps of:
making a magnetically free layer that is magnetized in a vortex shape in a plane perpendicular to a first direction in an absence of an external magnetic field and whose magnetization direction is variable in accordance with an external magnetic field,
making a magnetically pinned layer whose magnetization direction is fixed in the first direction, and
making a nonmagnetic layer located between the magnetically free layer and the magnetically pinned layer, wherein
the step of making the magnetically free layer includes applying a vortex dissipating magnetic field to the magnetically free layer in a direction different from the first direction to dissipate the vortex-shaped magnetization, and then stopping the application of the vortex dissipating magnetic field to generate magnetization in a vortex shape in the magnetically free layer whose magnetization direction at a center of the vortex shape is oriented in the direction opposite to the magnetization direction of the magnetically pinned layer.

12. The method for manufacturing a magnetoresistive element according to claim 11 wherein the nonmagnetic layer is made such that at least a part of a centerline of the nonmagnetic layer has a concavo-convex shape in a cross section parallel to the first direction.

13. The method for manufacturing a magnetoresistive element according to claim 11, wherein the magnetically pinned layer is made such that the magnetically pinned layer applies, through the nonmagnetic layer, a magnetic field to the magnetically free layer in the direction opposite to the magnetization direction of the magnetically pinned layer.

14. A method for manufacturing a magnetic sensor comprising a step of:
making a first element unit and a second element unit, each of which comprising at least one magnetoresistive element such that the first element unit and the second element unit are connected in series to form a first group, one end of the first group is connected to a power supply and other end is grounded, the first element unit is located on the side of the power supply, and the second element unit is located on the grounded side, wherein
each magnetoresistive element is made by the method for
manufacturing a magnetoresistive element according to claim 11, the magnetically pinned layers of the first and second element units are made such that a magnetization direction of the magnetically pinned layer of at least one magnetoresistive element included in the first element unit and a magnetization direction of the magnetically pinned layer of at least one magnetoresistive element included in the second element unit are oriented in opposite directions in the first direction.

15. A method for manufacturing a magnetic sensor comprising a step of:
making first through fourth element units, each of which comprising at least one magnetoresistive element such that the first element unit and the second element unit are connected in series to form a first group, the third element unit and the fourth element unit are connected in series to form a second group, one end of the first group and one end of second group are connected to a power supply and other ends are grounded, the first and fourth element units are located on the side of the power supply, and the second and third element units are located on the grounded side; and
making a differential circuit to determine a difference between an output that is between the first element unit and the second element unit and an output that is between the third element unit and the fourth element unit, wherein each magnetoresistive element is made by the method for
manufacturing a magnetoresistive element according to claim 11, the magnetically pinned layers of the first through fourth element units are made such that magnetization directions of the magnetically pinned layers of at least one magnetoresistive element included in each of the first and fourth element units and magnetization directions of the magnetically pinned layers of at least one magnetoresistive element included in each of the second and third element units are fixed in the first direction and are oriented in opposite directions to each other.
